(19) United States
(12) Patent Application Publication
(10) Pub. No.: US 2014/0060647 A1
(43) Pub. Date: Mar. 6, 2014

(54) CONCENTRATOR-TYPE PHOTOVOLTAIC RECEIVER HAVING HOMOGENIZER WITH FIXING STRUCTURE

(71) Applicants: Yueh-Mu Lee, (US); Yi-Ping Liang, (US); Hwen-Fen Hong, Longtan Township (TW); Hwa-Yuh Shin, Longtan Township (TW)

(72) Inventors: Yueh-Mu Lee, (US); Yi-Ping Liang, (US); Hwen-Fen Hong, Longtan Township (TW); Hwa-Yuh Shin, Longtan Township (TW)

(73) Assignee: ATOMIC ENERGY COUNCIL INSTITUTE OF NUCLEAR ENERGY RESEARCH

(21) Appl. No.: 13/604,488

(22) Filed: Sep. 5, 2012

(51) Int. Cl. H01L 31/0232

(52) U.S. Cl. 136/259

(57) ABSTRACT

The present invention relates to a concentrator-type photovoltaic receiver having homogenizer with fixing structure. The resent invention improves the structure of the homogenizer, which comprises a homogenizing part providing homogenizing function and a supporting part providing supporting and fixing function. The homogenizing part and the supporting part are formed integrally. The supporting part is a straight pillar. The user can bond the supporting part to the insulating substrate via glue and thus preventing the homogenizing part therein from collapse and contamination by dirt. Accordingly, good quality and lifetime can be maintained.

### FIELD OF THE INVENTION

The present invention relates generally to a homogenizer with fixing structure, and particularly to a homogenizer in a concentrator-type photovoltaic receiver.

### BACKGROUND OF THE INVENTION

Concentrator-type photovoltaic power generation acquires photo energy via a contractor-type photovoltaic receiver and enhances power generating efficiency by concentrating a great deal of photo energy. When solar energy is focused by the Fresnel lens, it will enter a transparent light-guiding pillar with a shape close to an upside-down pyramid, namely, a homogenizer. The bottom side of the homogenizer is a smooth surface with a main function of evening the energy of the light spot focused by the Fresnel lens. If the energy of the light spot is not evened by the homogenizer but illuminated directly on the solar cell, due to excess concentration of energy, the optoelectronic conversion efficiency is not well. In addition, because the incident angle of sunlight is not fixed but varies instantly with time, a tracker system is required for a concentrator-type solar-cell module. The tracker system will adjust to the optimum angle instantly according to the sunlight angle. The function of the homogenizer here is to improve the tolerance in angle of the tracker system as well as in dimensions during assembling. Thereby, it is an extremely important and functional device.

Currently, the homogenizer is still assembled manually. Owing to its functional requirement, the homogenizer is an inverted-pyramid-shaped device with a wide top and a narrow bottom. With the top-heavy property, it's difficult to control the accuracy during bonding. In other words, the homogenizer is bonded on the solar cell by glue, which is a sticky fluid before drying off. Thereby, before hardening, the homogenizer located on the glue tends to tilt slightly by external force. Or it tilts during manual assembly and topples gradually before the glue is hardened. Even if the homogenizer is tilted but not toppled over, during subsequent practical operations, it is no guarantee that the tracker system will not collapse under rotation.

In addition to the tilt and collapse problem, how to maintain surface cleanness of a homogenizer is another major problem. Because a homogenizer makes the incident light to reach uniformly and completely the concentrator-type solar cell at the bottom by means of internal total reflection, the cleanness of its side surface is the key point. If dirt or moisture exists on the surrounding surface of a homogenizer, total reflection will be destroyed, leading to light leakage and loss.

Besides, the contact interface of a homogenizer and glue contact may be the critical place where light leakage occurs. During manual assembly of a homogenizer, if the homogenizer is pressed excessively on the glue to make the homogenizer deep into the glue, the glue will be squeezed and pushed to the bottom surface of sides of the homogenizer and hence resulting in glue spill. Glue spill will cause loss in light energy. Consequently, the light energy reaching the concentrator-type solar cell is reduced and thus lowering the efficiency.

Refer to FIG. 1A. According to the prior art, at most, an external frame 4 is adopted for assisting gluing of the homogenizer 3 to the concentrator-type solar cell 11 on the insulating substrate 13. Nonetheless, the drawbacks described above will appear. The homogenizer 3 is still in an unstable status. It tends to tilt, move, or even collapse, and thus deteriorating the gluing quality substantially. In addition, the gluing height of the homogenizer 3 is not even, the final concentrator-type photovoltaic receiver will not have good receiving quality.

Moreover, refer to FIG. 1B. This is extracted from the US patent application US 2009/0223555. In the application, a hollow concentrating cup is disclosed. The concentrating cup is supported and fixed by means of the supporting stands on both sides. Although quality instability caused by gluing the homogenizer can be prevented, the optical efficiency of the concentrating cup cannot compete with the homogenizer. Besides, these supporting stands extending towards both sides occupy substantial space. If the concentrating cup is replaced by a homogenizer, the problem of light leakage and loss on side surfaces due to dirt accumulated after long-term usage will also occur.

Accordingly, because the instability of a homogenizer during gluing may introduce defects for a concentrator-type photovoltaic receiver, the present invention provides a concentrator-type photovoltaic receiver having homogenizer with fixed structure for solving the problem.

### SUMMARY

An objective of the present invention is to provide a concentrator-type photovoltaic receiver having homogenizer with fixed structure. The integrally-formed homogenizer has the function of isolating dirt, and hence extending the lifetime and quality of the concentrator-type photovoltaic receiver.

Another objective of the present invention is to provide a concentrator-type photovoltaic receiver having homogenizer with fixed structure. No extra frame to the homogenizer is required for assisting supporting the homogenizer. Thereby, the space occupied by a single photovoltaic receiver can be reduced.

Still another objective of the present invention is to provide a concentrator-type photovoltaic receiver having homogenizer with fixed structure. The homogenizer has an integrally-formed supporting structure, so that the originally unstable homogenizer can be fixed on the concentrator-type solar cell with certainty. Thereby, the stability of the concentrator-type photovoltaic receiver can be enhanced.

Still another objective of the present invention is to provide a concentrator-type photovoltaic receiver having homogenizer with fixed structure. The assembly is simple. In addition to more rapid assembly than the homogenizer according to the prior art, the assembly quality is also ensured.

For achieving the objectives described above, the present invention discloses a concentrator-type solar cell, glue, and a homogenizer. The glue is disposed on the concentrator-type solar cell; and the homogenizer is disposed on the glue. The homogenizer comprises a supporting part and a homogenizing part. The supporting part is a transparent hollow pillar, and further connects with an insulating substrate under the concentrator-type solar cell. The homogenizing part is a solid transparent body with its top wider than the bottom and disposed on the concentrator-type solar cell and at the center of the supporting part. A top-wide region of the homogenizing part connects with a top of the supporting part. Under such a structure, it is convenient to glue the homogenizer. In addition, tilt or collapse will not occur after gluing; the cleanness of the homogenizer can be maintained as well. Thereby, the bonding efficiency, the performance, and the lifetime of the homogenizer can be enhanced simultaneously.

### BRIEF DESCRIPTION OF THE DRAWINGS

FIG. 1A shows a schematic diagram of the gluing result according to the prior art;

FIG. 1B shows a schematic diagram of the concentrating cup according to the prior art;

FIG. 2 shows a structural schematic diagram of the homogenizer according to a preferred embodiment of the present invention;

FIG. 3 shows a three-dimensional diagram of the overall structure according to a preferred embodiment of the present invention;

FIG. 4A shows a cross-sectional view before gluing according to a preferred embodiment of the present invention;

FIG. 4B shows a cross-sectional view after gluing according to a preferred embodiment of the present invention;

FIG. 5A shows a cross-sectional view before gluing according to another preferred embodiment of the present invention;

FIG. 5B shows a cross-sectional view during gluing according to another preferred embodiment of the present invention;

FIG. 5C shows a cross-sectional view after gluing according to another preferred embodiment of the present invention;

FIG. 6A shows a bottom view of the cylindrical homogenizer according to a preferred embodiment of the present invention;

FIG. 6B shows a bottom view of the square-pillar homogenizer according to a preferred embodiment of the present invention; and

FIG. 6C shows a bottom view of the polyhedron homogenizer according to a preferred embodiment of the present invention.

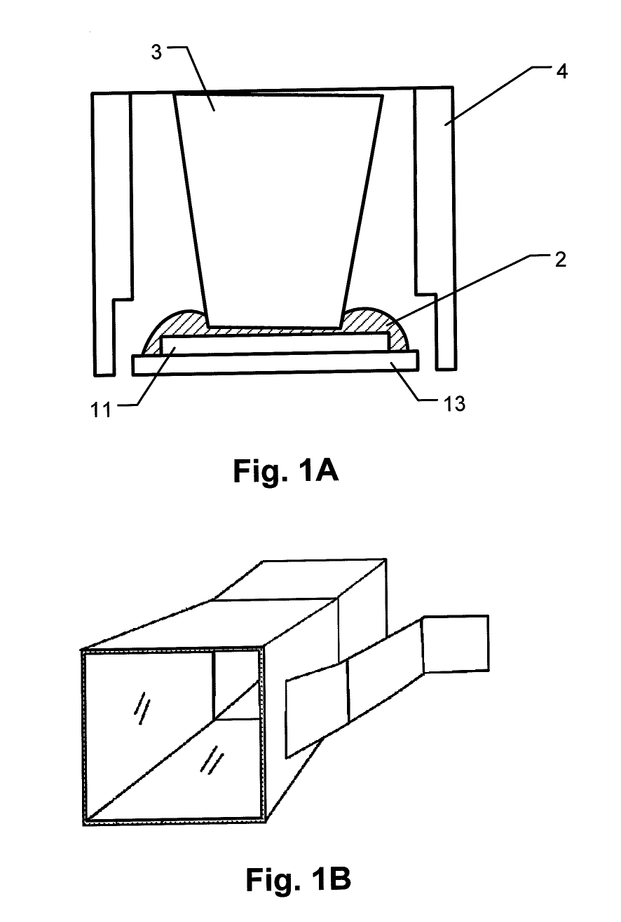

### DETAILED DESCRIPTION

In order to make the structure and characteristics as well as the effectiveness of the present invention to be further understood and recognized, the detailed description of the present invention is provided as follows along with embodiments and accompanying figures.

It is possible to produce defects during the bonding process of the homogenizer according to the prior art. Accordingly, for overcoming the technical defects, the present invention is provided for improving and solving the problems.

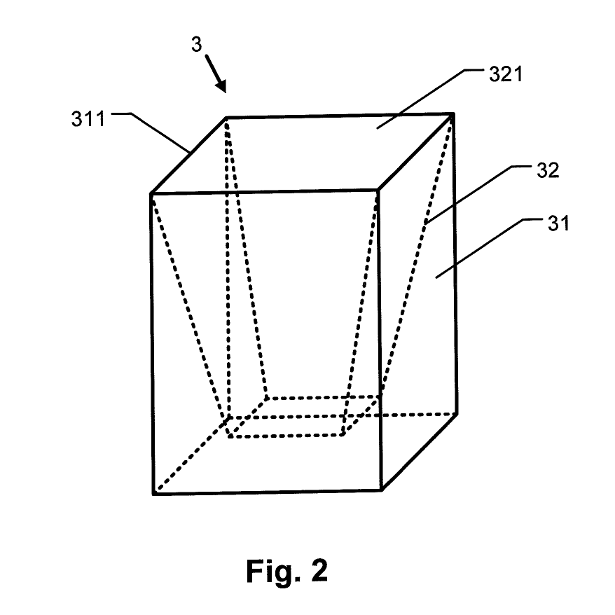

First, refer to FIG. 2. This figure discloses the structure of the homogenizer . according to the present invention, which structure also characterizes the present invention. As shown in the figure, the homogenizer 3 comprises a supporting part 31 and a homogenizer 32, which two are formed integrally. The supporting part 32 is a transparent hollow pillar, and particularly, a straight pillar. It provides the supporting function for the homogenizer 3. The homogenizing part 32, on the other hand, distributes the focused sunlight uniformly to the solar cell for the homogenizer 3.

The structure of the homogenizing part 32 is not limited to the inverted trapezoidal pillar; it could be a paraboloidal surface, similar to a bullet, or a semi-spherical body. Nonetheless, in general, the structure is a solid transparent body with its top wider than the bottom. Thereby, in order to be formed integrally with the supporting part 31, the homogenizing part 32 is located at the center of the supporting part 31. The top-wide region 321 is connected with the top 311 of the supporting part 31.

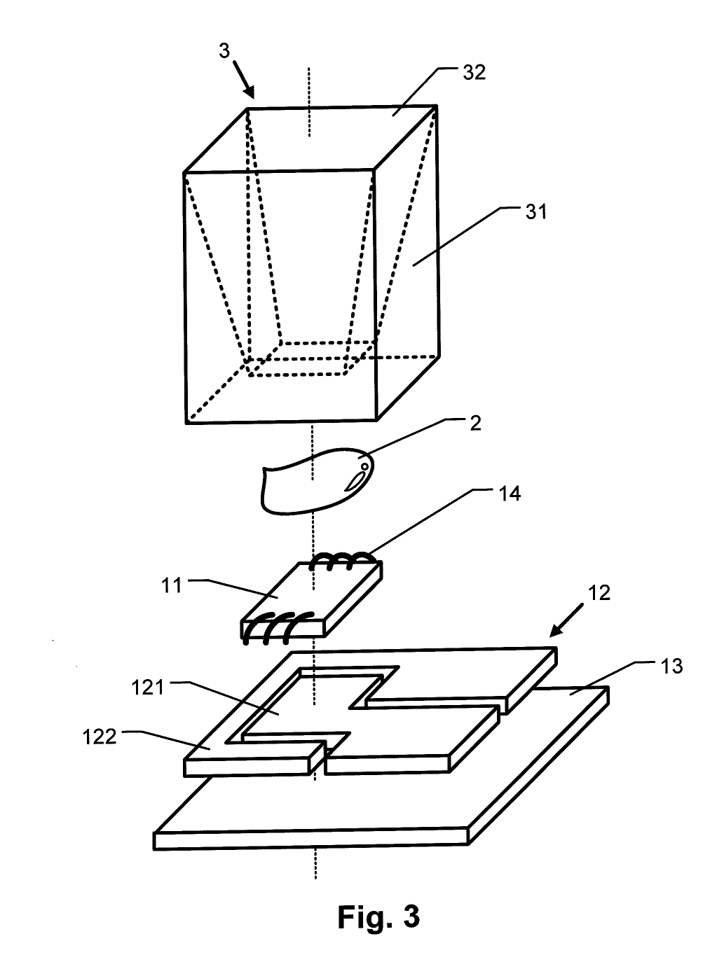

FIG. 3 discloses the schematic diagram of the relative locations of various devices during the application of the present invention. As shown in the figure, glue 2, a concentrator-type solar cell 11, a metal conducting layer 12, and an insulating substrate 13 are disposed below the homogenizer 3. The glue 2 is disposed on the concentrator-type solar cell 11. The metal conducting layer 12 is disposed between the concentrator-type solar cell 11 and the insulating substrate 13. The metal conducting layer 12 is a metal thin film used for electrical conduction. In practice, the thick of the metal conductive layer 12 is very thin. The thickness shown in the figure is only for expression purpose.

For the details of the structure, the metal conductive layer 12 cab be further divided into a first metal conductive layer 121 and a second metal conductive layer 122. The concentrator-type solar cell 11 is disposed on the first metal conductive layer 121. The electrodes at the bottom of the concentrator-type solar cell 11 are connected directly with the first metal conductive layer 121. In addition, the concentrator-type solar cell 11 is also connected electrically with the second metal conductive layer 122 via a plurality of metal wires 14 and hence forming a complete circuit. Moreover, the first and second metal conductive layers 121, 122 are connected with external circuitry and thus leading out electrical energy.

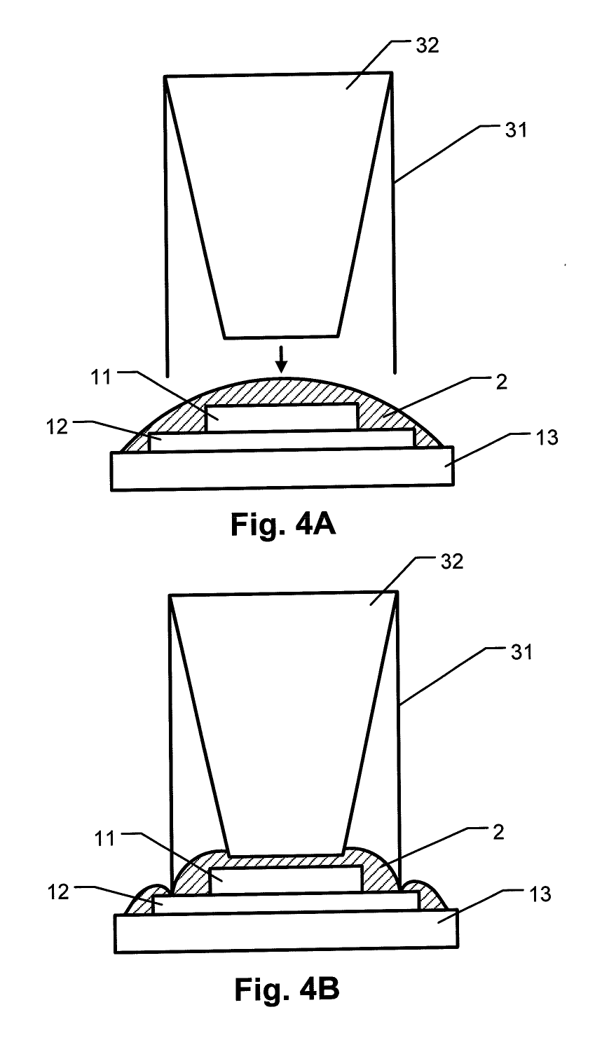

FIGS. 4A and 4B show cross-sectional views before and after gluing of the homogenizer 3 according to the present invention. During assembling the homogenizer 3 described above, because the homogenizing part 32 is located at the center of the supporting part 31 and the height thereof is smaller than the depth of the supporting part 31, as the supporting part 31 contacts the insulating substrate 13, the homogenizing part 32 of the homogenizer 3 will be located exactly above the concentrator-type solar cell 11 and contacts a portion of the glue 2. Thereby, the homogenizing part 32 can be bonded above the concentrator-type solar cell 11 via the glue 2. Meanwhile, the supporting part 31 will be fixed by the glue 2. Except for the top region, the homogenizing part 32 will be sealed and isolated. Thereby, external dirt will not contaminate the homogenizing part 32.

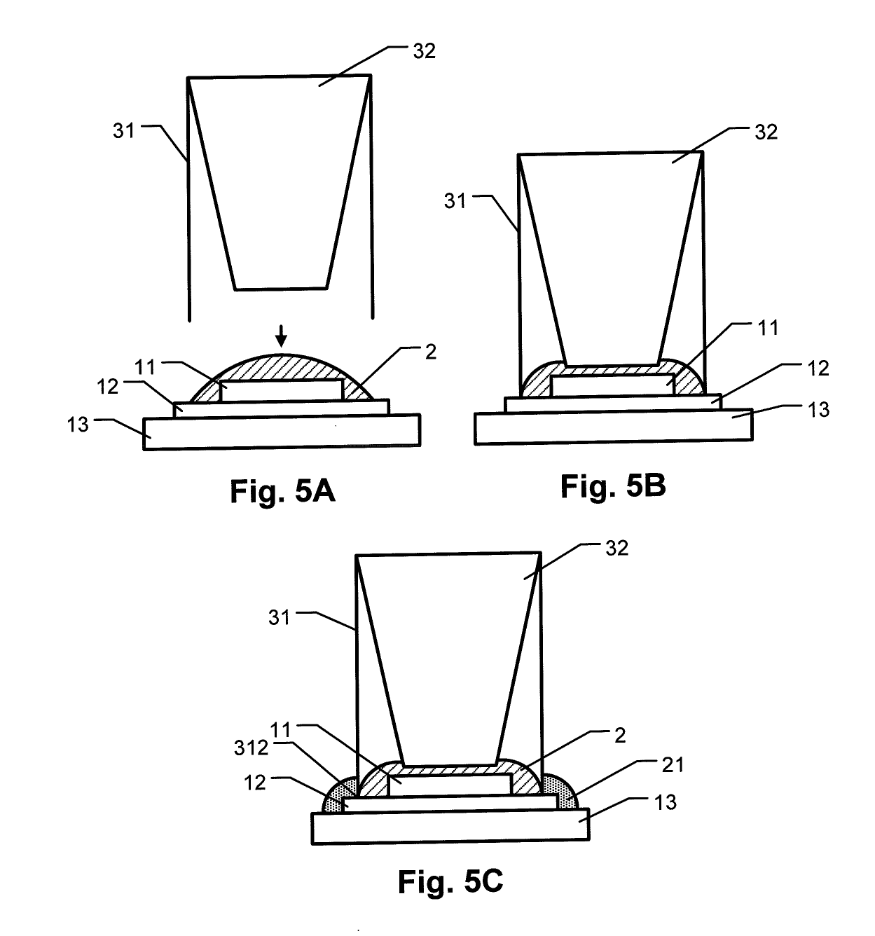

In addition to the bonding method described above, FIGS. 5A to 5C show another bonding method. As shown in the figure, in addition to the glue 2, external bonding glue 21, which is insulating and whose transparency is not required, can be used for assisting bonding. Then, the glue 2 is only used for bonding the homogenizing part 32 and the concentrator-type solar cell 11. On the other hand, the external bonding glue 21 is applied at the periphery of the bottom 312 of the supporting part 31 for further reinforcement. According to the present embodiment, normal insulating glue with lower cost is adopted for fixing the supporting part 31 on the insulating substrate 13. Thereby, the cost can be lowered and the selection of glue is flexible.

Without the assistance of the supporting part 31, the homogenizing part 32, which is top-heavy because of its top-wide and bottom-narrow structure, is difficult to be stabilized and fixed on the glue 2. Besides, it is also hard to maintain its horizontal position. By forming integrally with the supporting part 31, the bonding effect is enhanced by the help of the supporting part 31 and the homogenizing part 32 can stand stably on the concentrator-type solar cell 11.

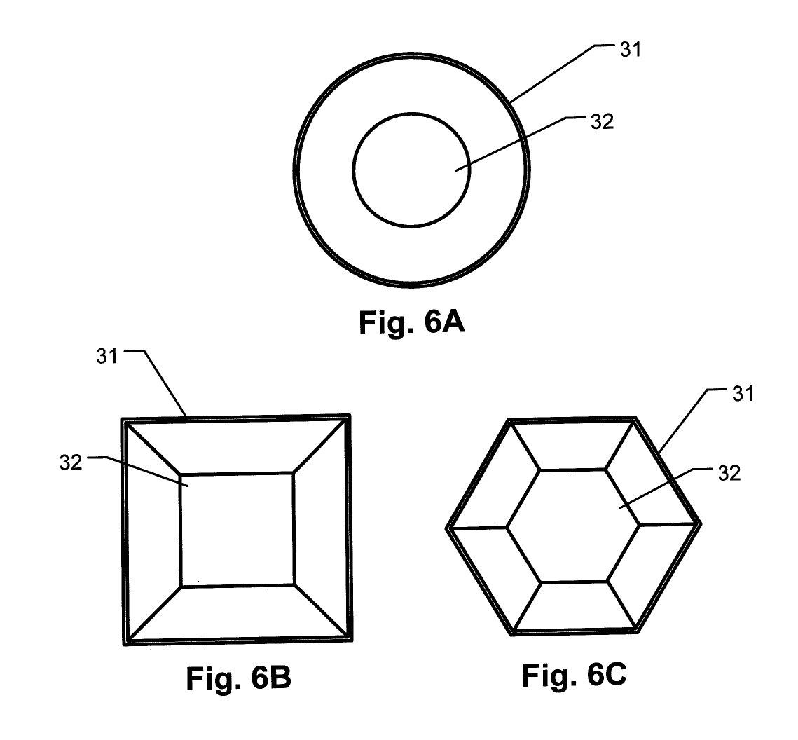

The shape of the supporting part 31 can be designed freely as a cylindrical pillar, a square pillar, or a polyhedral pillar depending on the shape of the homogenizing part 32, as long as the shape of the homogenizer 32 is a straight central pillar. FIGS. 6A to 6C show bottom views of the structure of the homogenizer 3. As shown in the figure, the homogenizing part 32 is truly located at the center of the supporting part 31. In addition, the thickness of the supporting part 31 is very thin. The critical point is on the flatness of the bottom for ensuring a horizontal position of the central homogenizing part 32 after assembly.

In the homogenizer 3, the heights of the supporting part 31 and the homogenizing part 32 are already fixed. Thereby, during assembling, the contact condition between the bottom of the homogenizing part 32 and the glue 2 can be stably controlled. Thereby, glue spill, caused by excessive reach of the homogenizing part 32 into the glue 2 and by pushes and squeezes of the glue 2 to the side surface of the homogenizing part 32, can be avoided. Consequently, the situation of light leakage caused by glue spill can be prevented accordingly.

Finally, in order to make the light pass through the homogenizer 3 and the glue 2 after being focused by Fresnel lens and reach the concentrator-type solar cell 11 smoothly, the material of the homogenizer 3 can be transparent high-polymer synthesized resin, glass, or quartz. The fabrication method is not limited. No matter die casting, grinding, molding, or ejection, once it's cost effective, the fabrication method can be adopted. Moreover, the glue 2 is insulating glue pervious to light. Thereby, conduction of the circuit of various conductive devices will not be affected by adherence of the glue 2.

The homogenizer in the concentrator-type photovoltaic receiver having homogenizer with fixing structure according to the present invention can have a better bonding result during assembling. The top-heavy homogenizer can be stable and not easy to collapse during the operation of a tracker system and thus extending the lifetime. In addition, the homogenizing part of the homogenizer can be protected from pollution of outdoor dirt. Moreover, because it is not required to fine-tune the locations of the homogenizer and the undried glue, manpower and time can be saved, leading to tremendous increase in assembling efficiency. Thereby, the present invention provides a concentrator-type photovoltaic receiver having substantial economic values.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A concentrator-type photovoltaic receiver having homogenizer with fixing structure, comprising:
a concentrator-type solar cell; and
a homogenizer, disposed on said concentrator-type solar cell, and comprising:
a supporting part, being a transparent hollow pillar, and connecting with an insulating substrate at the bottom of said concentrator-type solar cell; and
a homogenizing part, being a top-wide and bottom-narrow solid transparent body, disposed on said concentrator-type solar cell and located at the center of said supporting part, and having a top-wide region connected with a top of said supporting part.

2. The concentrator-type photovoltaic receiver having homogenizer with fixing structure of claim 1, wherein said supporting part and said homogenizer are formed integrally.

3. The concentrator-type photovoltaic receiver having homogenizer with fixing structure of claim 1, and further comprising glue, disposed between said concentrator-type solar cell and said homogenizing part of said homogenizer, and being insulating glue pervious to light.

4. The concentrator-type photovoltaic receiver having homogenizer with fixing structure of claim 1, and further comprising external bonding glue, disposed on the outer side of a bottom of said supporting part, and being insulating glue.

5. The concentrator-type photovoltaic receiver having homogenizer with fixing structure of claim 1, wherein the material of said homogenizer can be high-polymer synthesized resin, glass, or quartz.

6. The concentrator-type photovoltaic receiver having homogenizer with fixing structure of claim 1, wherein the height of said homogenizing part is smaller than the depth of said supporting part.

7. The concentrator-type photovoltaic receiver having homogenizer with fixing structure of claim 1, wherein said supporting part is a cylindrical pillar, a square pillar, or a polyhedral pillar.

8. The concentrator-type photovoltaic receiver having homogenizer with fixing structure of claim 1, and further comprising a metal conductive layer disposed between said concentrator-type solar cell and said insulating substrate.

9. The concentrator-type photovoltaic receiver having homogenizer with fixing structure of claim 8, wherein said metal conductive layer includes a first conductive layer and a second conductive layer.

10. The concentrator-type photovoltaic receiver having homogenizer with fixing structure of claim 9, wherein said first conductive layer is located below said concentrator-type solar cell.

11. The concentrator-type photovoltaic receiver having homogenizer with fixing structure of claim 9, wherein said second conductive layer is connected with said concentrator-type solar cell via a plurality of metal wires.
